(19) United States
(12) Patent Application Publication
(10) Pub. No.: US 2023/0232600 A1
(43) Pub. Date: Jul. 20, 2023

(54) A SYSTEM AND METHOD FOR PROTECTING CABINETS FROM EMI

(71) Applicant: Primozone Production AB, Löddeköpinge (SE)

(72) Inventors: Fredrik Stoltz, Löddeköpinge (SE); Joakim Van Der Schaaf, Löddeköpinge (SE)

(21) Appl. No.: 18/001,691

(22) PCT Filed: Jun. 3, 2021
(86) PCT No.: PCT/EP2021/064926

§ 371 Date: Dec. 13, 2022

(30) Foreign Application Priority Data
Jun. 17, 2020 (EP) 20180560.3

(51) Int. Cl. H05K 9/00

(52) U.S. Cl. CPC H05K 9/0007; H05K 9/0064

(57) ABSTRACT

The present invention relates to a grounding method and system for providing grounding and electromagnetic shielding to a cabinet configured for containing an ozone generator.

### FIELD OF THE INVENTION

The present invention relates to a grounding method and system for providing grounding and electromagnetic shielding to a cabinet configured for containing an ozone generator.

### BACKGROUND OF THE INVENTION

Electromagnetic radiations can affect many sensitive electronics and can cause a wide variety of different issues from a simple hiss on a communication line, to a total disruption of a safety-critical signal. As such, electromagnetic radiations affect a diverse range of sectors, including all consumer and industrial electronics. In general, the main purpose of effective electromagnetic shielding is to prevent electromagnetic interference (EMI) from influencing sensitive electronics.

In cabinets, effective electromagnetic shielding is achieved through the grounding of the hatch or door. As today, two standard solutions are commonly used: knitted metal wire strip or bendable fingers.

Knitted metal wire strip, where the outer surface consists of a metal mesh net, ensures large surface area of contact between the hatch and the cabinet. Bendable fingers are often made of heat treated metal, such as copper, coated with other metals for optimal contact and low resistance, thus ensuring optimal grounding.

Other solutions comprise shielding gaskets for cabinets employing different combination of spring clips, spring fingers or lips creating contact between the opportune surfaces, mostly by applying appropriate pressure upon interference fit between complementary opposite members.

Generally, large surface area of contact are necessary, between the hatch and the enclosure of cabinets suitable for containing ozone generators, to ensure good grounding.

However, very often current solutions do not allow for compliance with Electromagnetic compatibility (EMC) directive limits in electromagnetic emissions.

In addition, it appears very difficult to provide systems and methods that compensate for possible positioning faults, which lead to poor grounding.

Hence, an improved method and system for electromagnetic shielding of a cabinet for containing ozone generators would be advantageous, and in particular a more efficient and reliable method and system, for grounding an hatch to an enclosure of a cabinet for ozone generators, which ensure for compensation of a great deal of positioning faults, would be advantageous.

### OBJECT OF THE INVENTION

An object of the present invention is to provide an efficient grounding system for shielding a cabinet for ozone generator from EMI.

A further object of the present invention is to provide a cabinet for containing an ozone generator apparatus comprising a grounding system for providing earth connection and for shielding the ozone generator apparatus from interferences from electromagnetic radiations.

Another object of the present invention is to provide a cabinet containing an ozone generator apparatus and a method compensating for possible positioning faults, thus leading to an improved grounding and shielding from interferences generated by electromagnetic radiations.

An object of the present invention may also be seen as to provide an alternative to the prior art.

In particular, it may be seen as an object of the present invention to provide an efficient and reliable grounding and shielding system for providing earth connection to and for shielding from EMI an ozone generator apparatus, which solves the above mentioned problems of the prior art.

### SUMMARY OF THE INVENTION

The above described objects and several other objects are intended to be obtained in a first aspect of the invention by providing a cabinet for an ozone generator, the cabinet comprising: an enclosure for containing an ozone generator; a hatch for delimiting the enclosure; one or more grounding means for providing earth connection between the enclosure and the hatch.

The grounding means for providing earth connection between the enclosure and the hatch are means for providing ground or earth connection, thus allowing for reduction of interference from electromagnetic radiations.

The cabinet of the invention is an ozone generator cabinet, i.e. it is a cabinet suitable for containing an ozone generator.

In some embodiments, the enclosure of the cabinet of the invention contains the ozone generator.

The cabinet is therefore referred to as ozone generator cabinet within the text.

The hatch, such as a door, is a mean for delimiting or closing the enclosure.

In some embodiments, the grounding means comprises at least: an elastic system fasten to the enclosure; an elongated element having a first end and a second opposite end; the first end being fasten to the hatch, such as to an internal surface of the hatch, the second end adapted or configured to interfere with the elastic system.

An elastic system is a system having the ability of resisting to a distorting influence and to return to its original size and shape when that influence or force is removed.

In some embodiments, the elastic system is fasten to the internal surface of the enclosure.

The hatch may have an internal and external surface.

In some embodiments, the internal surface of the hatch is the surface facing the ozone generator contained in the cabinet when the hatch is closed.

The first end may be fasten to an internal surface of the hatch.

The elongated element may be an element extending out of the internal surface towards the opening of the enclosure, i.e. an element extending out in a direction normal to the internal surface of the hatch.

The second end of the elongated element is adapted or configured to interfere with the elastic system, such as by pressing one surface in contact with the elastic system.

In some embodiments, the elongated element is an elongated cylindrical body, such as a metal pin.

In some further embodiments, the enclosure comprises walls surrounding the ozone generator and at least one opening.

In some embodiments, the hatch provides access to the ozone generator located inside the enclosure through the opening.

The enclosure may be a container or a holder suitable for containing an ozone generator. The enclosure or container may surround the ozone generator and have an opening to access the ozone generator, which is delimited by the presence of a hatch or door.

In some further embodiments, the elastic system is fasten to at least one of the walls surrounding the ozone generator.

In some other embodiments, the elastic system is fasten to at least two of the walls surrounding the ozone generator.

The elastic system may be fasten to an edge of the at least two walls of said enclosure, i.e. in between two orthogonal walls.

In some further embodiments, the elastic system comprises at least an elastic element suspended in a holding element.

The elastic element may be or comprise a spring, such as a metal helical coil spring, and wherein the holding element may be or comprise a spring bracket holding the spring.

The holding element has the function of holding the elastic element.

The elastic system may be a spring system.

The spring system may comprise an elongated element, a spring and a spring holder element or bracket, wherein the spring holder element has the function of fastening and keeping the spring in tension.

In some embodiments, the spring may be a helical or coil spring, such as a compression spring.

A compression spring is defined as a spiral of wire that returns to its original shape after compression.

In some embodiments, the spring holder may be fasten to two normal walls thus allowing for suspension of the spring at one corner of the enclosure.

In some embodiments, the second end of the elongated element is adapted or configured to interfere with the elastic element in a direction substantially orthogonal to a spring axis, wherein the spring axis is the spring compression or wind axis.

The spring has two main axis: the compression axis, i.e. the axis along which compression occurs and the lateral or side axis, being the two axis orthogonal to each other.

The second end of the elongated element is adapted or configured to interfere, when the hatch is closing, with the elastic element, so that the surface of the second end gets in contact with surfaces of the elastic element, or compression spring, in a direction along the lateral axis of the compression spring.

Upon closure of the hatch, the second end of the elongated element gets in contact with the elastic element, in a direction along its lateral axis, producing deformation of the elastic element and contact between the surface of the second end of the elongated element and surfaces of the elastic element.

At the opening of the hatch, the contact is removed and the elastic element returns to its initial shape and size.

In some embodiments, the second end of the elongated element may engage with the elastic element.

In some other embodiments, the one or more grounding means are at least two grounding means located not more than 0.5 m in between each other.

The grounding means may be more than one and may be located in different positions within the enclosure and the hatch.

As a preferred layout, the positioning of the grounding means, in order to gain a EMI reduction complying with EMC directive limits in electromagnetic emissions, has be at a distance not larger than 0.5 m in between each other, such as less than 0.5, for example less than 0.4 m, such as less than 0.3 m.

The advantage of the use of the current invention derives by the specific interaction between the elongated element in a perpendicular direction with the elastic element, which is able to absorb a great deal of positing faults.

Even if not perfectly aligned, the interference between the second end of the elongated element and the elastic element, such as a compression spring, along a direction orthogonal to the spring compression axis, allows for sufficient points of contacts thus providing sufficient EMI shielding.

The layout of the one or more grounding means, according to the invention compensate for a great deal of positioning faults, as the elastic element or spring bends either way, upon closure of the hatch, in case the elongated element is positioned slightly to the right or the left on the elastic element.

The invention allows for optimal grounding properties employing small contact points generating high contact pressure between the elongated element and the elastic system.

The movement of the elastic element or spring against the elongated element and within its holder or bracket mechanically removes eventual oxide layers formed on the connecting parts, thus ensuring good electrical contact.

In a second aspect, the invention relates to an ozone generator apparatus comprising the cabinet according to the first aspect of the invention.

In a third aspect, the invention relates to a method for providing grounding and electromagnetic shielding to a cabinet containing an ozone generator according to the first aspect of the invention, the method comprising: closing the hatch, thereby allowing for the elongated element to interfere with the elastic system.

The first, second, third and other aspects and embodiments of the present invention may each be combined with any of the other aspects and embodiments. These and other aspects of the invention will be apparent from and elucidated with reference to the embodiments described hereinafter.

### BRIEF DESCRIPTION OF THE FIGURES

The cabinet for an ozone generator, the ozone generator apparatus and the method for providing grounding and electromagnetic shielding to the cabinet according to the invention will now be described in more details with regard to the accompanying figures. The figures show one way of implementing the present invention and are not to be construed as being limiting to other possible embodiments falling within the scope of the attached claim set.

FIG. 1A shows a graphical illustration of the cabinet for an ozone generator according to some embodiments of the invention.

FIG. 1B is an enlarged partial view of the cabinet focusing on the means for grounding according to some embodiments of the invention.

FIG. 2A and FIG. 2B are further enlarged partial view of the cabinet focusing on the means for grounding according to some embodiments of the invention while closing the hatch.

FIGS. 3, 4 and 5 show graphical illustrations of the elements of the means for grounding according to some embodiments of the invention.

### DETAILED DESCRIPTION OF AN EMBODIMENT

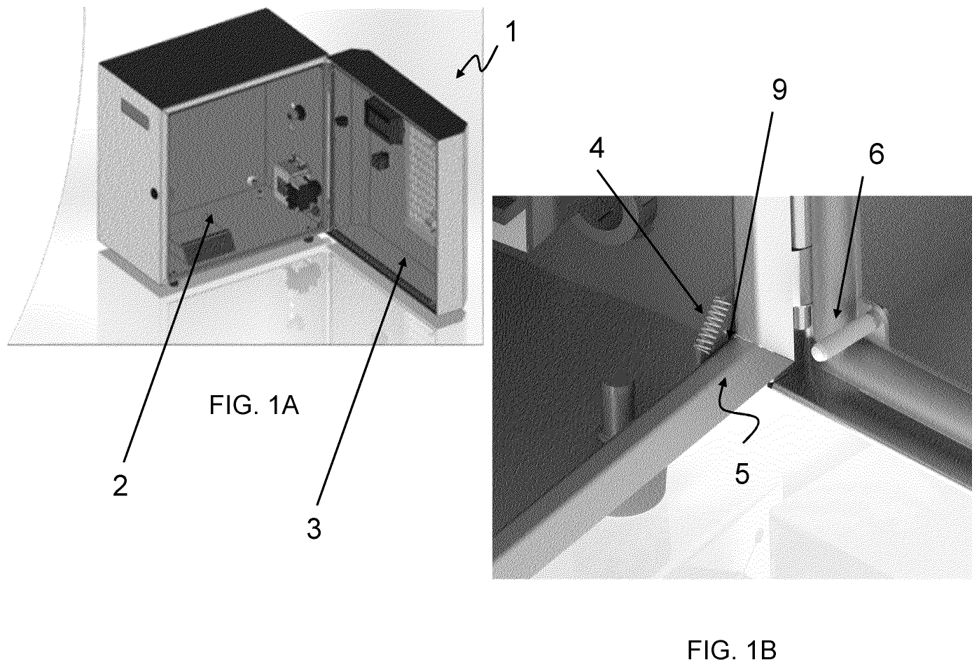

FIG. 1A shows a graphical illustration of the cabinet 1 for an ozone generator according to some embodiments of the invention.

The cabinet 1 consists of an enclosure or container 2 in which the ozone generator (not shown) is contained and a hatch or door 3 that delimits the container and provides closure for the cabinet.

The one or more grounding means providing earth connection between the enclosure 2 and the hatch 3 are shown in FIG. 1B as the elastic system 5 comprising a spring 4 supported on a spring bracket 9 and a pin 6, according to some embodiments of the invention.

The spring bracket 9 is fasten inside the enclosure 2 at one corner.

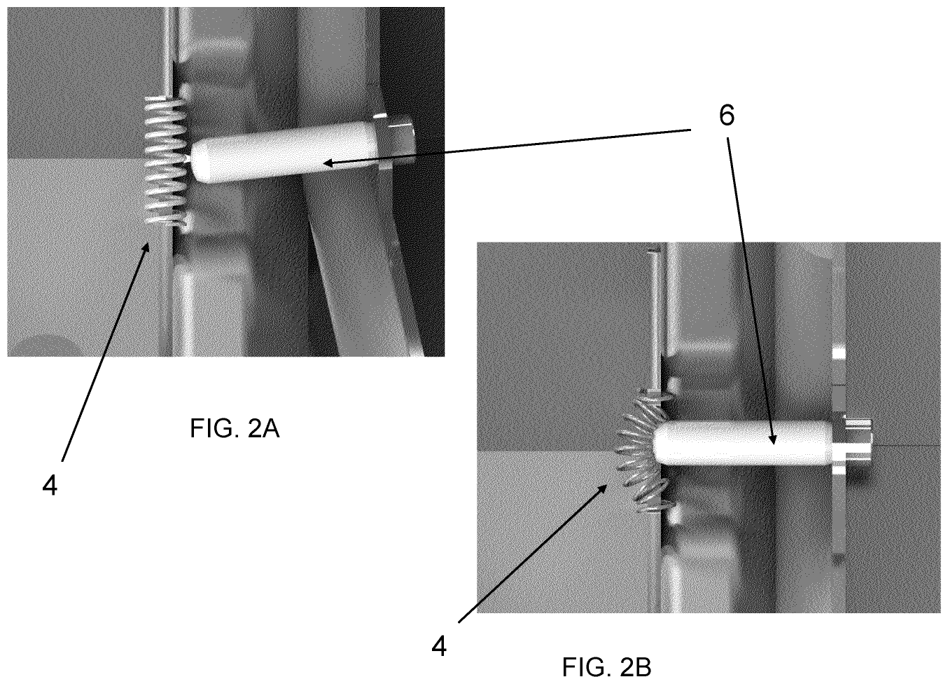

The closure of the hatch 3 generates a ground connection as the pin 6 interferes with the spring 4 located on the spring bracket 9 as shown in FIG. 2A and FIG. 2B.

As clearly seen in FIGS. 2A and 2B, the pin 6 interferes with the spring 4 in a perpendicular direction to the compression axis of the spring 4.

The flexibility of spring 4 allows for a great deal of positing faults, so that even if pin 6 and spring 4 are not perfectly aligned, the points of contacts between the two elements provide sufficient EMI shielding so as to comply with EMC directive limits.

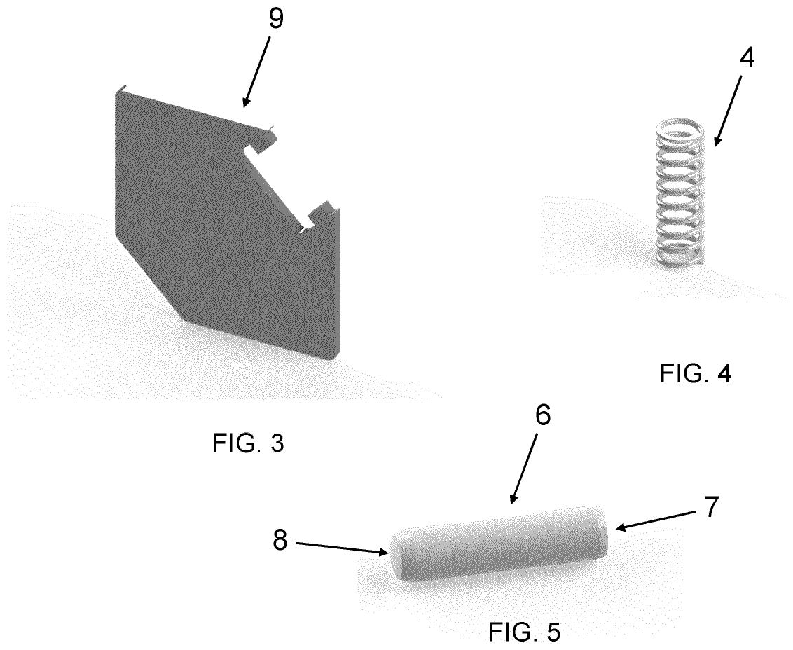

FIGS. 3, 4 and 5 show a graphical illustration of the spring bracket 9, the spring 4 and the pin 6 having a first end 7 fasten to the hatch and a second end 8 configured to interfere with the spring 4 supported by the spring bracket 9 according to some embodiments of the invention.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. In addition, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

1. A cabinet for an ozone generator, said cabinet comprising:
an enclosure for containing an ozone generator, wherein said enclosure comprises walls surrounding said ozone generator and at least one opening;
a hatch for delimiting said enclosure;
one or more grounds between said enclosure and said hatch; wherein said one or more grounds comprise at least:
an elastic system fastened to at least two of said walls surrounding said ozone generator; wherein said elastic system comprises at least an elastic element suspended in a holder element and wherein said elastic element comprises a metal helical coil spring, and wherein said holder element comprises a spring bracket holding said metal helical coil spring;
an elongated element having a first end and a second opposite end; said first end being fastened to said hatch, said second end configured to interfere with said elastic system; and wherein said second end is configured to interfere with said metal helical coil spring in a direction substantially orthogonal to a metal helical coil spring axis and, wherein said metal helical coil spring axis is the metal helical coil spring compression axis.

2-12. (canceled)

13. The cabinet according to claim 1, wherein said enclosure contains said ozone generator.

14. The cabinet according to claim 1, wherein said elastic system is a spring system.

15. The cabinet according to claim 1, wherein said elongated element is an elongated cylindrical body.

16. The cabinet according to claim 1, wherein said one or more grounds are at least two grounds located not more than 0.5 m in between each other.

17. An ozone generator apparatus comprising said cabinet according to claim 1.

18. A method for providing grounding and electromagnetic shielding to a cabinet containing an ozone generator, said cabinet comprising:
an enclosure for containing an ozone generator, wherein said enclosure comprises walls surrounding said ozone generator and at least one opening;
a hatch for delimiting said enclosure;
one or more grounds between said enclosure and said hatch; wherein said one or more grounds comprise at least:
an elastic system fastened to at least two of said walls surrounding said ozone generator; wherein said elastic system comprises at least an elastic element suspended in a holder element and wherein said elastic element comprises a metal helical coil spring, and wherein said holder element comprises a spring bracket holding said metal helical coil spring;
an elongated element having a first end and a second opposite end; said first end being fastened to said hatch, said second end configured to interfere with said elastic system; and wherein said second end is configured to interfere with said metal helical coil spring in a direction substantially orthogonal to a metal helical coil spring axis, wherein said metal helical coil spring axis is the metal helical coil spring compression axis;
said method comprising:
closing said hatch, thereby allowing for said elongated element to interfere with said elastic system.

19. The method according to claim 18, wherein said enclosure contains said ozone generator.

20. The method according to claim 18, wherein said elastic system is a spring system.

21. The method according to claim 18, wherein said elongated element is an elongated cylindrical body.

22. The method according to claim 18, wherein said one or more grounds are at least two grounds located not more than 0.5 m in between each other.
